(19) United States
(12) Patent Application Publication
(10) Pub. No.: US 2025/0279332 A1
(43) Pub. Date: Sep. 4, 2025

(54) FREQUENCY-SELECTIVE HEAT DISSIPATING DEVICE AND THIN FILM

(71) Applicant: Gwangju Institute of Science and Technology, Gwangju (KR)

(72) Inventors: Jong Seok Lee, Gwangju (KR); Do-Gyeom Jeong, Gwangju (KR)

(21) Appl. No.: 19/069,587

(22) Filed: Mar. 4, 2025

(30) Foreign Application Priority Data
Mar. 4, 2024 (KR) 10-2024-0030865
Mar. 4, 2025 (KR) 10-2025-0027762

(51) Int. Cl. H01L 23/373

(52) U.S. Cl. CPC H01L 23/3735

(57) ABSTRACT

A thin film including an amorphous layer between a first material and a second material, the amorphous layer including an amorphous compound of the first material and the second material, and a heat dissipating device including the thin film in which the composition ratio of the first material and the second material within the amorphous layer gradually changes along the thickness direction of the amorphous layer are provided.

### CROSS-REFERENCE TO RELATED APPLICATION

This application claims priority to and the benefit of Korean Patent Application No. 10-2024-0030865 filed with the Korean Intellectual Property Office on Mar. 4, 2024, and Korean Patent Application No. 10-2025-0027762 filed with the Korean Intellectual Property Office on Mar. 4, 2025, the entire contents of which are incorporated herein by reference.

### BACKGROUND

### 1. Field

This invention relates to a thin film and a heat dissipating device that transmits phonons depending on their frequency.

This research was supported by the Samsung Science & Technology Foundation (reference number: SRFC-MA2102-01).

### 2. Related Art

As electronic devices shrink in size to the nanoscale, heat dissipation is one of the critical challenges that must be addressed to ensure life-span and functionality of the devices. In particular, recent central processing units (CPUs) consume more than 100 W of electric power per square centimeter, which further emphasizes the importance of the heat dissipation.

Thermal management in the nanoscale devices is complicated and exacerbated by interfaces between different materials, which can significantly contribute to thermal resistance. Therefore, research is being conducted to minimize thermal boundary resistance (TBR) at various Nano-interfaces.

Meanwhile, strong boundary scattering at the Nano-interface can change the heat conduction characteristics of classical mechanics. For example, the thermal conductivity at the Nano-interfaces can be calculated as the sum of the contributions of all phonon modes.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a thin film structure includes: an amorphous layer between a first material and a second material, wherein the amorphous layer comprises an amorphous compound of the first material and the second material and a ratio of the first material and the second material in the amorphous layer gradually changes along thickness direction of the amorphous layer.

A first proportion of the first material may be substantially maximum where the amorphous layer is adjacent to the first material and a second proportion of the second material may be substantially maximum where the amorphous layer is adjacent to the second material.

The first material may be metal, the second material may be Gallium arsenide, and the amorphous layer may include a compound of the metal and the Gallium arsenide.

The thin film may further include: a first crystalline layer between the first material and the amorphous layer; and a second crystalline layer between the second material and the amorphous layer, wherein a first proportion of the first material may be substantially maximum where the amorphous layer is adjacent to the first crystalline layer and a second proportion of the second material may be substantially maximum where the amorphous layer is adjacent to the second crystalline layer.

The first crystalline layer may include a crystalline structure of the first material and the second crystalline layer may include a crystalline structure of the second material.

The thin film may further include an oxide layer between the first material and the amorphous layer, wherein a first proportion of the first material may be substantially maximum where the amorphous layer is adjacent to the oxide layer and a second proportion of the second material may be substantially maximum where the amorphous layer is adjacent to the second material.

The thin film may further include a first single amorphous layer between the first material and the oxide layer, wherein the first single amorphous layer may include an amorphous structure of the first material.

the first material may be metal and the second material may be Germanium.

The thin film may further include a first single amorphous layer comprising the first material, a second single amorphous layer comprising the second material, and a graphene layer, wherein the first single amorphous layer may be between the first material and the graphene layer, the graphene layer may be between the first single amorphous layer and the amorphous layer, and the second single amorphous layer may be between the amorphous layer and the second material.

The first single amorphous layer may include an amorphous structure of the first material and the second single amorphous layer may include an amorphous structure of the second material.

The first material may be metal and the second material may be Gallium arsenide or Silicon.

The thin film may further include: a graphene layer, wherein the graphene layer may be inserted in a middle of the amorphous layer.

In another general aspect, a heat dissipating device includes: a metal layer; a semiconductor layer; and a thin film positioned between the metal layer and the semiconductor layer, wherein the thin film may include an amorphous compound of metal of the metal layer and a semiconductor of the semiconductor layer and first proportion of the metal gradually decreases within the thin film and second proportion of the semiconductor gradually increases within the thin film along a direction from a first boundary between the thin film and the metal layer to a second boundary between the thin film and the semiconductor layer.

### BRIEF DESCRIPTION OF THE DRAWINGS

FIG. 1A illustrates a heat dissipating device that transfers heat between a high temperature material and a low temperature material according to one or more embodiments.

FIG. 1B illustrates heat transport of phonons between a high-temperature material and a low-temperature material according to one or more embodiments.

FIG. 2 illustrates a measurement system performing heat phonon transmission spectroscopy according to one or more embodiments.

FIG. 3A and FIG. 3B illustrate a heat dissipating device according to one or more embodiments.

FIG. 3C illustrates a method for manufacturing a heat dissipating device according to one or more embodiments.

FIG. 4A to FIG. 4C illustrate compositional changes of a heat dissipating device according to one or more embodiments.

FIG. 5A illustrates phonon transmission coefficients measured at an interface of heat dissipating devices according to one or more embodiments.

FIG. 5B and FIG. 5C illustrate spectral TBC of heat dissipating devices according to one or more embodiments.

FIG. 6A illustrates phonon transmission coefficients measured at an interface of heat dissipating devices according to one or more embodiments.

FIG. 6B illustrates spectral TBC of heat dissipating devices according to one or more embodiments.

FIG. 7A and FIG. 7B illustrate a heat dissipating device according to one or more embodiments.

FIG. 7C illustrates a method for manufacturing a heat dissipating device according to one or more embodiments.

FIG. 8A and FIG. 8B illustrate compositional changes of a heat dissipating device according to one or more embodiments.

FIG. 9A illustrates phonon transmission coefficients measured at an interface of heat dissipating devices according to one or more embodiments.

FIG. 9B and FIG. 9C illustrate spectral TBC of heat dissipating devices according to one or more embodiments.

FIG. 10A illustrates a heat dissipating device according to one or more embodiments.

FIG. 10B illustrates a method for manufacturing a heat dissipating device according to one or more embodiments.

FIG. 11A illustrates a heat dissipating device according to one or more embodiments.

FIG. 11B illustrates a method for manufacturing a heat dissipating device according to one or more embodiments.

FIG. 12A to FIG. 12C illustrate compositional changes of a heat dissipating device according to one or more embodiments.

FIG. 13A illustrates phonon transmission coefficients measured at an interface of heat dissipating devices according to one or more embodiments.

FIG. 13B illustrates spectral TBC of heat dissipating devices according to one or more embodiments.

FIG. 14 illustrates phonon transmission coefficients measured at an interface of GaAs series heat dissipating devices according to one or more embodiments.

FIG. 15 illustrates spectral TBC of GaAs series heat dissipating devices according to one or more embodiments.

FIG. 16A illustrates scattering ratios for the frequency of the heat dissipating device GaAs I according to one or more embodiments.

FIG. 16B illustrates scattering ratios for the frequency of the heat dissipating device GaAs IV according to one or more embodiments.

FIG. 17A illustrates spectral TBC about a function of a low-frequency filter of the heat dissipating device GaAs II according to one or more embodiments.

FIG. 17B illustrates spectral TBC about a function of a high-frequency filter of the heat dissipating device Ge IV according to one or more embodiments.

FIG. 17C illustrates spectral TBC about a function of a frequency conversion filter of the heat dissipating device GaAs IV according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

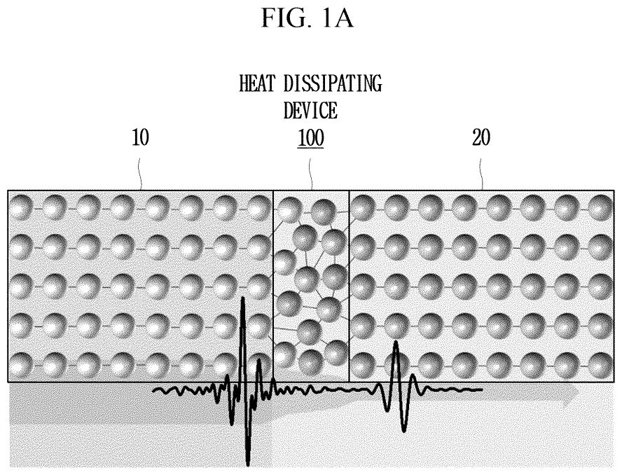

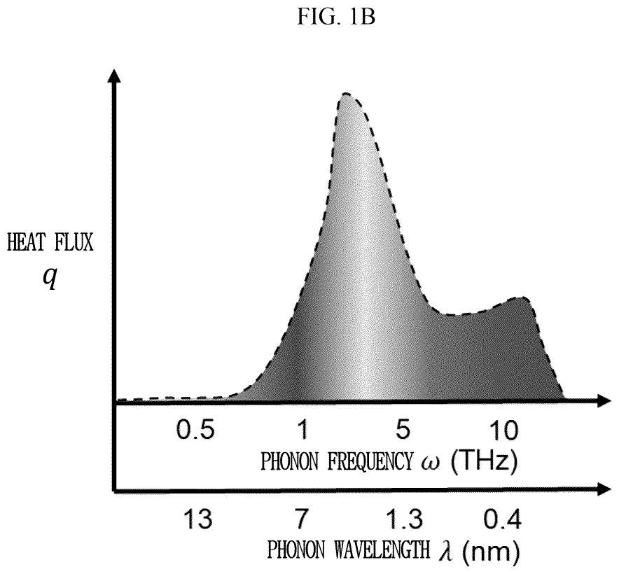

FIG. 1A illustrates a heat dissipating device that transfers heat between a high temperature material and a low temperature material according to one or more embodiments. FIG. 1B illustrates heat transport of phonons between a high-temperature material and a low-temperature material according to one or more embodiments.

Atoms are arranged in a regular manner within a material, and heat can be conducted within the material or between adjacent materials through lattice vibration of the arranged atoms. A phonon is a quasi-particle that represents a quantized lattice vibration of the atoms in the material. At a nanoscale, the heat can be understood as being transported by the phonon.

In general, the thermal conductivity for heat flow in a material is expressed as a function of the temperature of the material and the frequency of the phonons in the material. However, when the thickness of the material is reduced to the nanoscale, the thermal conductivity no longer has temperature as a variable due to the strong boundary scattering of the phonons. This means that temperature loses its usefulness as a control parameter to describe the heat flow, and the frequency of the phonons can function as the parameter to describe the heat flow at the interface between the materials.

Referring to FIG. 1A, heat can be transported from a high temperature material 10 to a low temperature material 20 through phonon transmission in a heat dissipating device 100 from the high temperature material 10 to the low temperature material 20. In some embodiments, the high temperature material 10 may be metal and the low temperature material 20 may be non-metal, such as a semiconductor. The metal may include Aluminum (Al), and the semiconductor may include any one of silicon (Si), germanium (Ge), and Gallium arsenide (GaAs). The high temperature material 10 and the low temperature material 20 are crystalline and may be monocrystalline or polycrystalline.

In some embodiments, the heat dissipating device 100 can minimize the phonon scattering at the material boundaries and increase phonon transmission through crystalline control and/or distribution design of materials within the heat dissipating device 100. In some embodiments, the heat dissipating device 100 may be a thin film having a thickness in the nanometer scale. The heat dissipating device 100 may include a compound layer of the high temperature material 10 and the low temperature material 20, and the compound layer may be crystalline and/or amorphous. The heat dissipating device 100 may further include an oxide layer and/or a graphene layer.

FIG. 1B illustrates heat flux transported within a material (Silicon (Si)) as a function of the frequency/wavelength of the phonon. Referring to FIG. 1B, the phonons with frequencies ranging from 0.5 Thz to 40 Thz or wavelengths ranging from 0.1 nm to 10 nm transport 99% of the heat in the silicon. In the following, a frequency band of the phonons responsible for the heat transport is referred to as a heat transfer band. In some embodiments, a heat dissipating device 100 may be designed to transmit as much of the phonons of the heat transport band from the high temperature material 10 to the low temperature material 20 as possible.

Heat transport performance of the heat dissipating device 100 may be determined according to a phonon transmission coefficient. In some embodiments, the phonon transmission coefficient of the heat dissipating device 100 may be determined through a heat phonon transmission spectroscopy (HPTS) performed based on time-domain thermo-reflectance (TDTR) measurements and first-principle calculations.

In some embodiments, the TDTR measurements may be performed to measure thermal characteristics of the heat dissipating device 100 in a nanoscale. In the TDTR measurement for the heat dissipating device 100, metal (the high temperature material) may act as a thermal transducer.

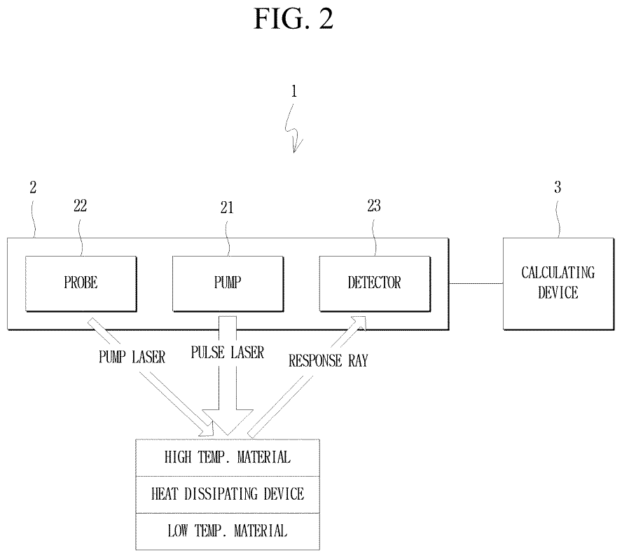

FIG. 2 illustrates a measurement system performing heat phonon transmission spectroscopy according to one or more embodiments.

Referring to FIG. 2, a measurement system 1 according to one or more embodiments may include a measuring device 2 and a calculating device 3. The measuring device 2 may include a pump 21, a probe 22, and a detector 23.

In the TDTR measurement, the pump 21 of the measuring device 2 may irradiate a rapidly oscillating pulse laser to metal, and the probe 22 of the measuring device 2 may irradiate a pump laser to the metal after the pulse laser for a predetermined time delay.

For example, the pump 21 may use a Titanium-sapphire (Ti:sapphire) laser with repetition speed fᵣₑₚ=80 MHz as the pulse laser. The probe 22 may use the pump laser modulated at five frequencies between f_{mod}=3.80 MHz to 12.0 MHz. The pulse laser and the pump laser may cause the metal to act as a vibrational heat source with a vibration frequency fₕₑₐₜ(=mfᵣₑₚ±f_{mod}) (m is a real number greater than or equal to 0).

When the pulse laser and the pump laser are irradiated on a surface of the metal, response rays corresponding to the two time-delayed lasers may be measured by the detector 23. In some embodiments, the TDTR responses along the response rays may be determined as a sum of a surface temperature response (H) of the metal and a thermal vibration frequency (fₕₑₐₜ). Equation 1 below represents the TDTR response Z measured by the measuring device 2.

$$Z ( t , {f}_{m od} ) = {{\sum }_{m = - ∞}}^{∞} H ( {f}_{heat} = {mf}_{rep} + {f}_{m od} ) \cdot exp ( i 2 π {mf}_{r ep} t ) \qquad Equation 1$$

The computing device 3 may perform operations necessary for the heat phonon transmission spectroscopy analysis based on the results measured by the measuring device 2.

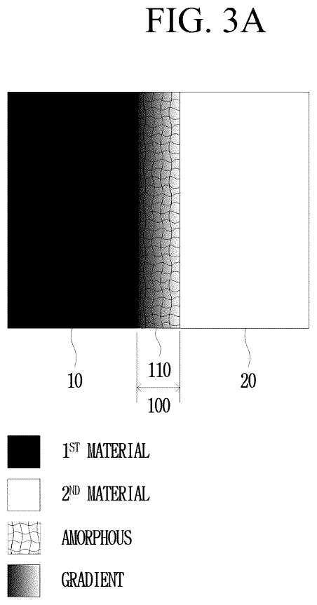

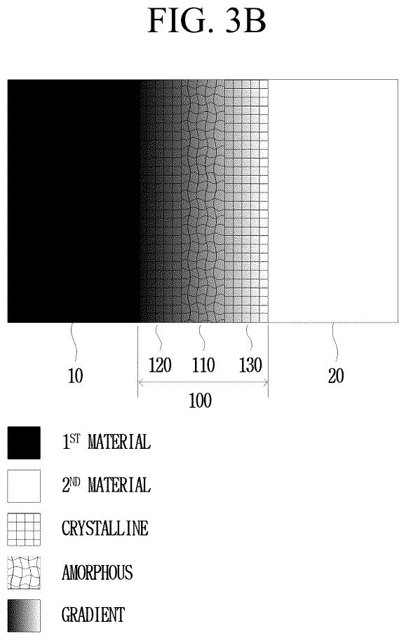

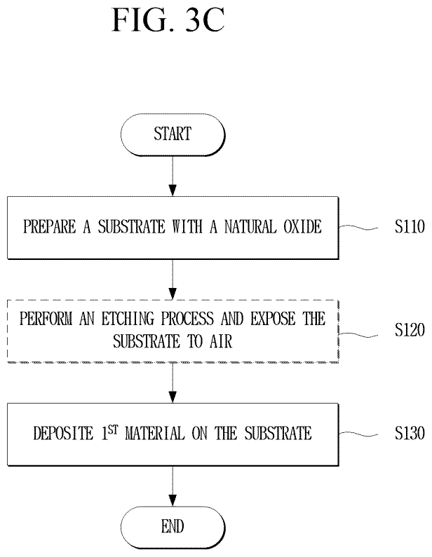

FIG. 3A and FIG. 3B illustrate a heat dissipating device according to one or more embodiments.

Referring to FIG. 3A, a heat dissipating device 100 according to one or more embodiments includes an amorphous layer 110. The amorphous layer 110 is between a first boundary where the heat dissipating device 100 is adjacent to a first material 10 and a second boundary where the heat dissipating device 100 is adjacent to a second material 20.

Referring to FIG. 3A, the amorphous layer 110 may include an amorphous compound of the first material 10 and the second material 20. Within the amorphous layer 110, a ratio of the first material 10 and the second material 20 may gradually change along a thickness direction of the amorphous layer 110. That is, the amorphous layer 110 may have a concentration gradient of the first material 10 and the second material 20. For example, along the direction from the first boundary to the second boundary, a first proportion of the first material 10 in the amorphous layer 110 may gradually decrease and a second proportion of the second material 20 may gradually increase. The first proportion of the first material 10 may be substantially maximum in a part adjacent to the first boundary and the second proportion of the second material 20 may be substantially maximum in a part adjacent to the second boundary.

Referring to FIG. 3B, the heat dissipating device 100 may further include a first crystalline layer 120 and a second crystalline layer 130 including crystalline compounds of the first material 10 and the second material 20. In FIG. 3B, the first crystalline layer 120, the amorphous layer 110, and the second crystalline layer 130 may have a continuous concentration gradient. For example, along the direction from the first crystalline layer 120 to the second crystalline layer 130, the first proportion of the first material 10 may gradually decrease and the second proportion of the second material 20 may gradually increase. In the first crystalline layer 120, the first proportion of the first material 10 may be higher than that of the second material 20, in the amorphous layer 110, the proportions of the first material 10 and second material 20 may be similar, and in the second crystalline layer 130, the second proportion of the second material 20 may be higher than that of the first material 10.

In some embodiments, the heat dissipating device 100 may be generated by depositing the first material 10 on a substrate including the second material 20. Referring to FIG. 3C, a substrate with a natural oxide may be prepared S110. The substrate may be a commercially available substrate and include semiconductor materials such as silicon, Gallium arsenide, or germanium.

Afterwards, a process of etching may be performed to remove the natural oxide from the substrate depending on the type of the heat dissipating device 100 and the substrate with the natural oxide layer removed may be exposed to air S120. For example, hydrofluoric acid (HF) may be used in the etching process.

The first material 10 may be deposited on the substrate S130. When the first material 10 is deposited with a predetermined thickness or for a predetermined time, an amorphous layer 110 including the amorphous compound of the first material 10 and the second material 20 may be formed.

Table 1 shows characteristics of the manufacturing process of the heat dissipating device 100, in which Gallium arsenide (GaAs), germanium (Ge), or silicon (Si) is used as the second material 20.

TABLE 1

| 2^{nd} material | Index | etching process | air expose duration after etching |
|---|---|---|---|
| GaAs | I | ∘ | 30 min. or less |
| GaAs | II | x | N/A |
| Ge | I | ∘ | 30 min. or less |
| Ge | II | ∘ | 2 days |
| Si | I | x | N/A |
| Si | II | ∘ | 1 day |
| Si | III | ∘ | 30 min. or less |
| Si | IV | ∘ | 2 days |

Referring to Table 1, the etching process may be performed to remove the natural oxide layer when the heat dissipating devices GaAs I is manufactured from a Gallium arsenide substrate, the heat dissipating devices Ge I and Ge II are manufactured from a germanium substrate, and the heat dissipating devices Si II, Si III, and Si IV are manufactured from a silicon substrate. The etching process may make the surface of the substrate metastable. The thickness of the heat dissipating device may increase depending on the length of the exposal time for each substrate after the etching process.

When a metal that is good at intercalation between layers of other materials (e.g., Al) is deposited on the substrate, the thickness of the amorphous layer and the crystalline layer may vary depending on the characteristics of the second material of the substrate.

In some embodiments, Gallium arsenide may be strongly bonded to the metal (e.g., Al) as an ion-bonded semiconductor material. Therefore, the Gallium arsenide substrate may rapidly form a dense amorphous layer by reacting with the metal deposited on the surface, and the penetration of the metal into the lower part of the substrate may be suppressed by the amorphous layer containing the metal-Gallium arsenide compound. Therefore, GaAs I and GaAs II may not contain the crystalline layers (the first crystalline layer and the second crystalline layer).

In some embodiments, since the surface of GaAs I having a dense structure is stable because the etching process is not performed on the surface of GaAs I, Al may shallowly penetrate into GaAs I. As a result, the thickness of the amorphous layer of GaAs I may be thinner than the thickness of the amorphous layer of GaAs II on which the etching process is performed.

In some embodiments, germanium and silicon may be bonded relatively weakly to the metal as a covalent-bonded semiconductor material. Therefore, the germanium substrate and the silicon substrate may react with the metal deposited on the surface to form the amorphous layer, and the metal may penetrate relatively deeper into the substrate.

For example, a part where the metal penetrates most deeply and a crystalline structure of a compound of the metal and the semiconductor material (a covalent-bonded semiconductor such as the germanium substrate or the silicon substrate) is formed may be referred to as the second crystalline layer adjacent to the substrate (i.e., the second material). In addition, a part where the metal and the semiconductor material are mixed in similar proportions and the amorphous structure of the compound of the metal and the semiconductor material is formed may be referred to as the amorphous layer. Further, a part where the metal is mixed with a little bit of semiconductor material to form the crystalline structure of the compound of the metal and the semiconductor material may be referred to as the first crystalline layer adjacent to the metal (i.e., the first material).

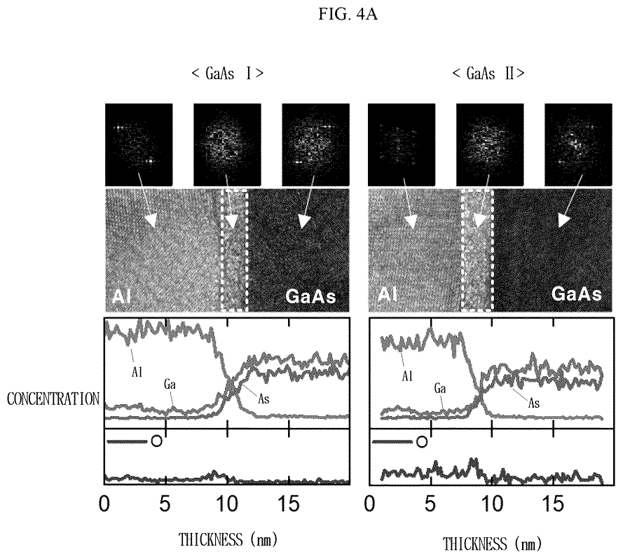

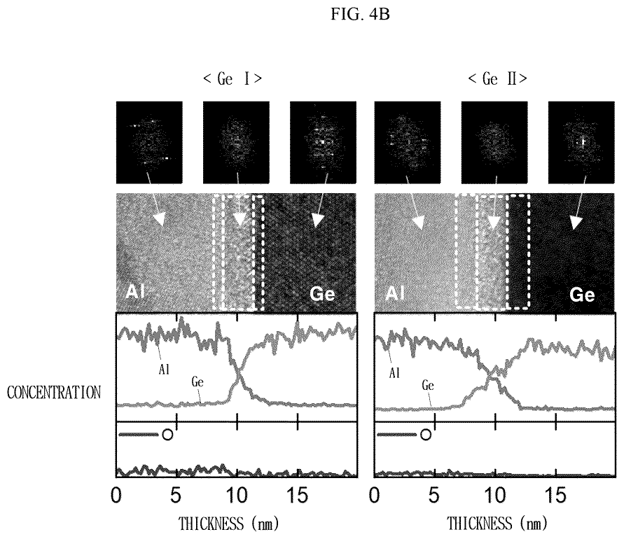

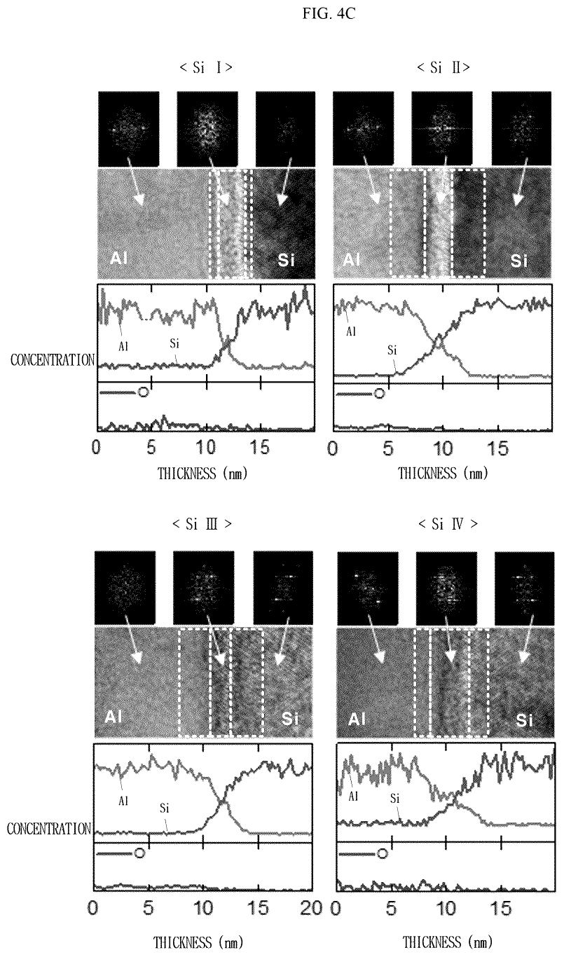

FIG. 4A to FIG. 4C illustrate compositional changes of a heat dissipating device according to one or more embodiments.

FIG. 4A to FIG. 4C illustrate transmission electron microscope (TEM) images and energy dispersion X-ray spectroscopy (EDS) depth profiles of the first material, the second material, and the heat dissipating device positioned between the first material and the second material. The fast Fourier transform (FFT) images of specific portion of the first material, the heat dissipating device, and the second material in the TEM image are listed in the upper part of FIG. 4A to FIG. 4C.

In FIG. 4A, the first material is polycrystalline aluminum (Al) and the second material is a monocrystalline Gallium arsenide (GaAs) substrate. In FIG. 4B, the first material is polycrystalline aluminum (Al) and the second material is a monocrystalline germanium (Ge) substrate. In FIG. 4C, the first material is polycrystalline aluminum (Al) and the second material is monocrystalline silicon (Si) substrate.

Referring to FIG. 4A and FIG. 4B, in the TEM images, the first material (Al) is shown in a light shade and the second materials (GaAs and Ge) are shown in a relatively dark shade. Referring to FIG. 4C, in the TEM image, the first material (Al) is shown in a light shade and the second material (20, Si) is shown in a slightly darker shade than the first material. In FIG. 4A to FIG. 4C, dotted line boxes between the first material and the second material represent layers included in the heat dissipating device.

In the EDS depth profiles of FIG. 4A to FIG. 4C, the O line at the bottom represents the concentration of oxygen measured in the first material, the heat dissipating device, and the second material. During the fabrication of the heat dissipating device, the first material and the second material may react with the oxygen in the air, so trace amounts of oxygen may be present in the first material, the heat dissipating device, and the second material.

In FIG. 4A, the heat dissipating devices GaAs I and GaAs II may include an amorphous layer including an amorphous compound of aluminum and Gallium arsenide. For example, the heat dissipating devices GaAs I and GaAs II may have a layered structure such as that shown in FIG. 3a.

The dotted line box in the TEM image of FIG. 4A may represent the amorphous layer of aluminum-Gallium arsenide compound included in the heat dissipating devices GaAs I and GaAs II, respectively. In the fabrication of GaAs I, an etching process has been performed, and an air exposure process of less than 30 minutes has been performed after the etching process. In the fabrication of GaAs II, no etching process was performed, and therefore no air exposure process was performed.

In the FFT images of FIG. 4A, both the FFT images of the first material (Al) and second material (GaAs) portion include well-defined diffraction peaks (particularly bright spots), which may indicate that the first material portion and second material portion are highly crystalline. On the other hand, the FFT image of the heat dissipating device portion does not show the diffraction peak, which may indicate the amorphous characteristic of the heat dissipating device.

In FIG. 4A, the EDS depth profile of GaAs I may show a concentration gradient of the first material and the second material. In GaAs I, the aluminum concentration remains high before a 1.3 nm thick amorphous layer within the heat dissipating device, then gradually decreases within the amorphous layer, and becomes substantially zero at the right interface of the amorphous layer. In contrast, the concentration of Gallium arsenide remains substantially 0 before the amorphous layer, then gradually increases within the amorphous layer, and reaches a substantially maximum at the right interface of the amorphous layer.

In FIG. 4A, the EDS depth profile of GaAs II may show the concentration gradient of the first material and the second material. In GaAs II, the aluminum concentration remains high before a 2.1 nm thick amorphous layer of the heat dissipating device, then gradually decreases within the amorphous layer, and becomes substantially zero at the right interface of the amorphous layer. In contrast, the concentration of Gallium arsenide remains substantially 0 before the amorphous layer, then gradually increases within the amorphous layer, and reaches a substantially maximum at the right interface of the amorphous layer.

In FIG. 4B, the heat dissipating devices Ge I and Ge II may include an amorphous layer including an amorphous compound of aluminum and germanium, a first crystalline layer (Al crystalline layer) positioned on one side of the amorphous layer, and a second crystalline layer (Ge crystalline layer) positioned on the other side of the amorphous layer. For example, the heat dissipating devices Ge I and Ge II may have a layered structure such as that shown in FIG. 3b.

The dotted line boxes in the TEM image of FIG. 4B may represent the first crystalline layer-amorphous layer-second crystalline layer of the aluminum-germanium compound included in the heat dissipating devices Ge I and Ge II, respectively.

In some embodiments, the etching process has been performed to fabricate Ge I and Ge II, the air exposure process of less than 30 minutes has been performed to fabricate Ge I, and the air exposure process of about two days has been performed to fabricate Ge II. By the difference of the air exposure process, Ge II may include a thicker first crystalline layer and a thicker second crystalline layer than Ge I.

In the FFT image of FIG. 4B, both the FFT images of the first material (Al) and second material (Ge) portion include well-defined diffraction peaks, which may indicate that the first material portion and second material portion are highly crystalline. On the other hand, the FFT image of the heat dissipating device portion does not show a diffraction peak, which may indicate the amorphous characteristic of the heat dissipating device.

In FIG. 4B, the EDS depth profiles of Ge I and Ge II may show the concentration gradients of the first material and the second material. In Ge I and Ge II, the aluminum concentration remains high before the first crystalline layer within the heat dissipating device, then gradually decreases within the first crystalline layer, the amorphous layer, and the second crystalline layer, and becomes substantially zero at the right interface of the second crystalline layer. In contrast, the concentration of germanium remains substantially 0 before the first crystalline layer, then gradually increases within the first crystalline layer, the amorphous layer, and the second crystalline layer, and reaches a substantially maximum at the right interface of the second crystalline layer.

Referring to FIG. 4B, in a heat dissipating device including a thick amorphous layer and a thick crystalline layer, the concentration gradients of the first material and the second material may tend to be more gradual. For example, because Ge II includes a thicker crystalline layer than Ge I, the concentration gradient of materials within Ge II is more gradual than the concentration gradient of materials within Ge I.

In FIG. 4C, the heat dissipating devices Si I, Si II, Si III, and Si IV may include an amorphous layer including an amorphous compound of aluminum and silicon, a first crystalline layer (Al crystalline layer) positioned on one side of the amorphous layer, and a second crystalline layer (Si crystalline layer) positioned on the other side of the amorphous layer. For example, the heat dissipating devices Si I, Si II, Si III, and Si IV may have a layered structure such as that shown in FIG. 3b.

The dotted line boxes in the TEM image of FIG. 4C may represent the first crystalline layer-amorphous layer-second crystalline layer of the aluminum-silicon compound included in the heat dissipating devices Si I, Si II, Si III, and Si IV, respectively. Si II, Si III, and Si IV may include a first crystalline layer and a second crystalline layer that are thicker than Si I.

In some embodiments, the etching process was not performed to fabricate Si I, and the etching process has been performed to fabricate Si II, Si III, and Si IV. For the production of Si II, Si III, and Si IV, an air exposure process of about one day, an air exposure process of less than 30 minutes, and an air exposure process of about two days were performed, respectively.

In the FFT image of FIG. 4C, both the FFT images of the first material (Al) and second material (Si) portion include well-defined diffraction peaks, which may indicate that the first material and second material portion are highly crystalline. On the other hand, the FFT image of the heat dissipating device portion does not show the diffraction peak, which may indicate the amorphous characteristic of the heat dissipating device.

In FIG. 4C, the EDS depth profiles of Si I, Si II, Si III, and Si IV may show the concentration gradients of the first material and the second material. In Si I, Si II, Si III, and Si IV, the aluminum concentration remains high before the first crystalline layer within the heat dissipating device, then gradually decreases within the first crystalline layer, the amorphous layer, and the second crystalline layer, and becomes substantially zero at the right interface of the second crystalline layer. In contrast, the silicon concentration remains substantially 0 before the first crystalline layer, then gradually increases within the first crystalline layer, the amorphous layer, and the second crystalline layer, and reaches a substantially maximum at the right interface of the second crystalline layer. In Si II, Si III, and Si IV, the sum of the thicknesses of the first crystalline layer, the amorphous layer, and the second crystalline layer are greater than 5 nm.

Referring to FIG. 4C, in a heat dissipating device including a thick amorphous layer and a crystalline layer, the concentration gradients of the first material and the second material may tend to be more gradual. For example, because Si II includes a thicker crystalline layer than Si I, the concentration gradient of the material within Si II is more gradual than the concentration gradient of materials of Si I.

Below, phonon transport performance of the heat dissipating devices shown in FIG. 3A and FIG. 3B is described through related graphs.

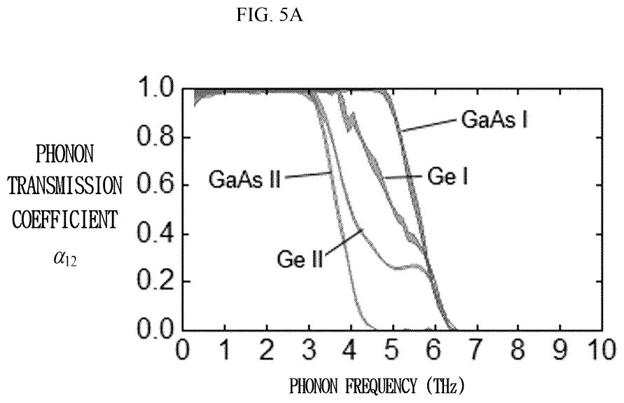

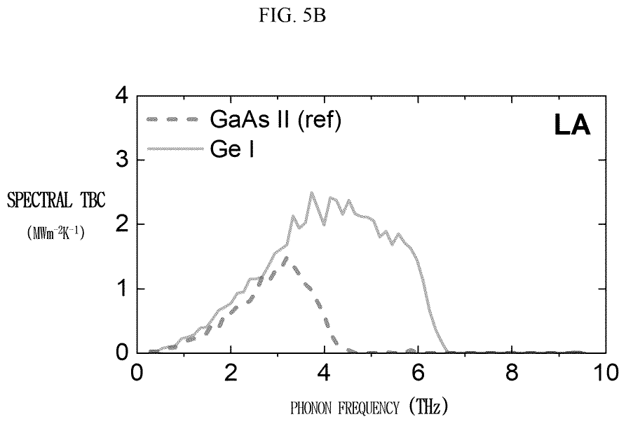

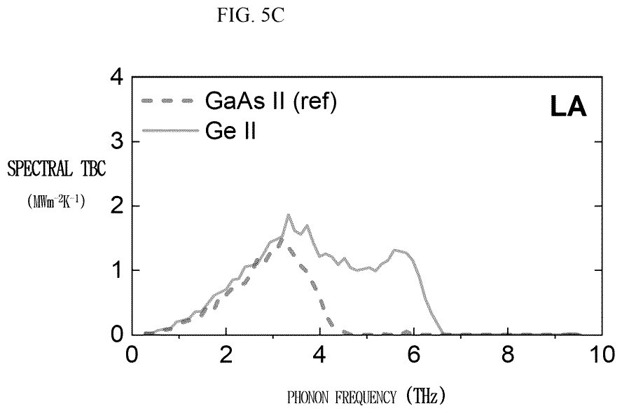

FIG. 5A illustrates phonon transmission coefficients measured at an interface of heat dissipating devices according to one or more embodiments. FIG. 5B and FIG. 5C illustrate spectral TBC of heat dissipating devices according to one or more embodiments.

Referring to FIG. 5A, phonon transmission coefficients of four different heat dissipating devices GaAs I, GaAs II, Ge I, and Ge II as a function of phonon frequency are shown. FIG. 5A illustrates the transmission coefficients of phonons in the longitudinal acoustic (LA) mode in the heat dissipating devices. In FIG. 5A, the longitudinal direction is the direction from medium 1 (e.g., first material 10) to medium 2 (e.g., heat dissipating device 100). That is, the longitudinal direction is the thickness direction of the heat dissipating device.

The phonon transmission coefficient α₁₂ of phonons transmitted at the interface between medium 1 and medium 2 may be calculated as shown in equation 2 below.

$${α}_{12} = \frac{\frac{{τ}_{12}}{{L}_{Z}}}{\frac{3}{4 {v}_{1}} + \frac{1}{2} ( 1 + β ) \frac{{t}_{12}}{{L}_{Z}}} \qquad Equation 2$$

In equation 2, 1/τ₁₂ represents a scattering rate of the phonons at an interface between medium 1 and medium 2, and L_{z} is a spacing of superlattices within each medium, which represents a distance between periodically arranged scattering sources. In equation 2, β represents a ratio of thermal energy transferred by the phonons in each medium. β is shown in equation 3 below.

$$β = \frac{{C}_{1} {v}_{1}}{{C}_{2} {v}_{2}} \qquad Equation 3$$

In equation 3, C₁ is the specific heat of the medium 1, v₁ represents group velocity of phonons propagating in the medium 1, C₂ is the specific heat of the medium 2, and v₂ represents group velocity of phonons propagating in the medium 2.

Since the heat dissipating devices of FIG. 5A tend to transmit relatively low-frequency phonons, the heat dissipating devices including only one amorphous layer (GaAs I and GaAs II) and heat dissipating devices including the amorphous layer and crystalline layers (Ge I and Ge II) may be used as low-pass filters that may transmit low-frequency phonons.

In GaAs I and GaAs II including only the amorphous layer (see FIG. 3A), the phonon transmission coefficient decreases at 5 THz and 3 THz, respectively, and the decreasing pattern of the phonon transmission coefficient is consistent and smooth.

In Ge I and Ge II (see FIG. 3B) which include additional crystalline layers on both sides of the amorphous layer, the phonon transmission coefficient decreases at 3.8 THz and 3 THz, respectively, and the decrease in the phonon transmission coefficient is not consistent. For example, phonons between 5 THz and 6 THz may be transmitted at the interface of Ge II with the phonon transmission coefficient greater than 0.2. It may be determined that Ge I and Ge II may transmit higher frequency phonons compared to GaAs II.

FIG. 5B and FIG. 5C illustrate spectral thermal boundary conductance (TBC) of the heat dissipating devices Ge I and Ge II as a function of phonon frequency, compared to that of the heat dissipating device GaAs II. FIG. 5B and FIG. 5C illustrate the spectral TBC of the LA mode phonons in the heat dissipating device.

The thermal boundary conductivity @@@ may be expressed by equation 4 below.

$$G ( ω ) = ℏω D ( ω ) \frac{\partial {f}_{0} ( ω , T )}{\partial T} v ( ω ) \frac{1}{8 {π}^{3}} {α}_{12} ( ω ) \qquad Equation 4$$

In equation 4, ℏ is the reduced Planck constant, ω is the phonon frequency, D(ω) is the frequency-dependent phonon state density, and T is the temperature of the medium. Also, f₀(ω, T) is the Bose-Einstein distribution with the frequency of phonons and the temperature of the medium as variables, v(ω) is group velocity of phonons, and @@@ is the phonon transmission coefficient at the interface of the medium 1 and the medium 2.

The area enclosed by the graph in FIG. 5B and FIG. 5C represents the total TBC, and the total TBC is larger for Ge I and Ge II than for GaAs II. Therefore, it may be determined that Ge I and Ge II, which include more crystalline layers on both sides of the amorphous layer, may transport phonons in a relatively higher frequency domain than GaAs II, and as a result, may transfer a larger amount of thermal energy corresponding to the high frequency phonon at the interface of the medium 1 and the medium 2.

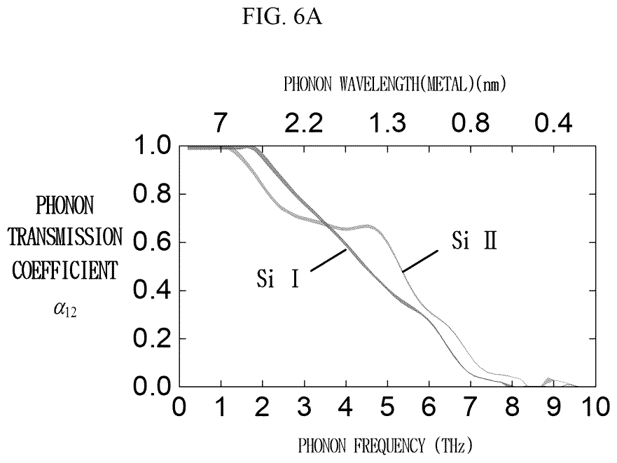

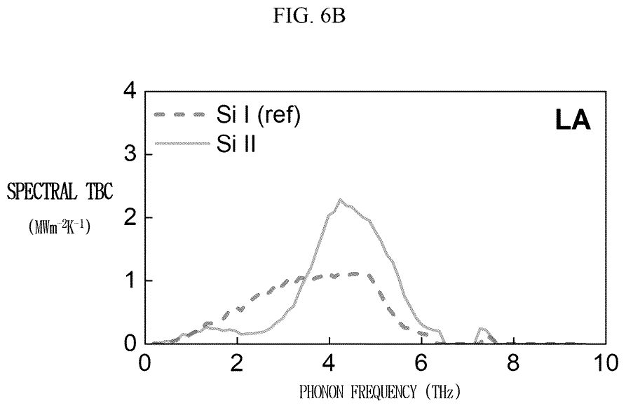

FIG. 6A illustrates phonon transmission coefficients measured at an interface of heat dissipating devices according to one or more embodiments.

Referring to FIG. 6A, the phonon transmission coefficients of two different heat dissipating devices Si I and Si II as a function of the phonon frequency are shown. FIG. 6A illustrates the transmission coefficient of LA mode phonons in the heat dissipating devices.

FIG. 6B illustrates the spectral TBC of the heat dissipating devices Si I and Si II as a function of the phonon frequency. FIG. 6B illustrates the spectral TBC of the LA mode phonons in the heat dissipating devices.

Referring to FIG. 6A, the heat dissipating devices Si I and Si II tend to transmit higher frequency phonons than the GaAs series and Ge series heat dissipating devices above, and therefore may be used as a high pass filter that may transmit relatively high frequency phonons.

Referring to FIG. 6A, it is shown that Si II, which includes relatively thicker first and second crystalline layers, has a smaller corner frequency than Si I, but SI II transmits phonons with frequencies from 4 THz to 6 THz. This is also clearly shown in FIG. 6B. Referring to FIG. 6B, the total TBC is larger for Si II than for Si I at frequencies from 4 THz to 6 THz. Therefore, it may be determined that Si II, which includes thicker crystalline layers on both sides of the amorphous layer, transmits higher frequency phonons at the interface between the medium 1 and the medium 2 better than Si I which includes thinner crystalline layers.

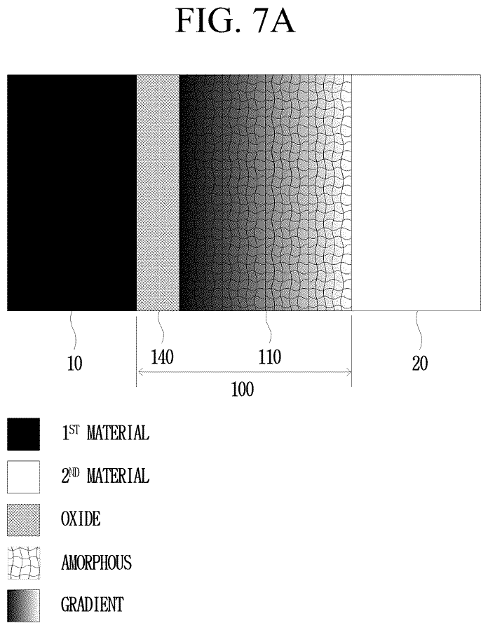

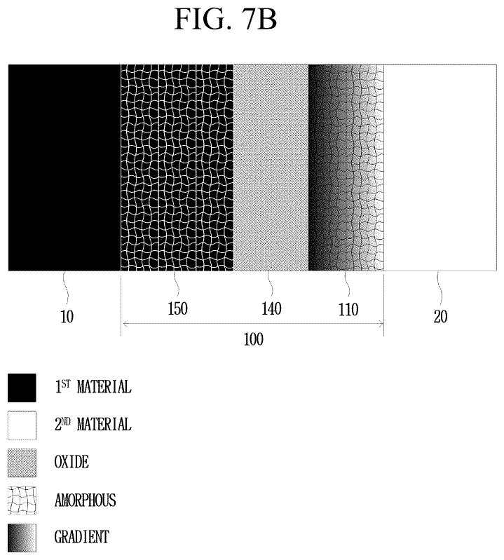

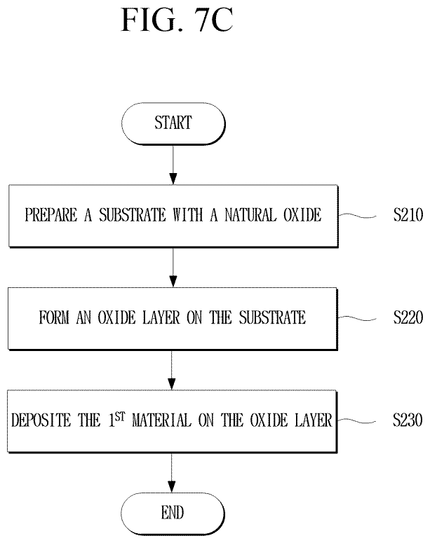

FIG. 7A and FIG. 7B illustrate a heat dissipating device according to one or more embodiments.

Referring to FIG. 7A, a heat dissipating device 100 according to one or more embodiments includes an amorphous layer 110 and an oxide layer 140. The amorphous layer 110 is between the second material 20 and the oxide layer 140, and the oxide layer 140 is between the amorphous layer 110 and the second material 10.

Referring to FIG. 7A, the amorphous layer 110 may include an amorphous compound of the first material 10 and the second material 20. Within the amorphous layer 110, a ratio of the first material 10 and the second material 20 may gradually change along the thickness direction of the amorphous layer 110. That is, the amorphous layer 110 may have a concentration gradient of the first material 10 and the second material 20. For example, along the direction from the oxide layer 140 to the second material 20, the first proportion of the first material 10 in the amorphous layer 110 may gradually decrease and the second proportion of the second material 20 may gradually increase. The first proportion of the first material 10 may be substantially maximum in the part where the amorphous layer 110 is adjacent to the oxide layer 140, and the second proportion of the second material 20 may be substantially maximum in the part where the amorphous layer 110 is adjacent to the second material 20.

Referring to FIG. 7B, the heat dissipating device 100 may further include a first single amorphous layer 150 of the first material 10. In FIG. 7B, the first single amorphous layer 150 may substantially include only the first material 10 and may be formed after the oxide layer 140 is formed.

The chemical composition of the amorphous layer 110 in FIG. 7B may be the substantially same as the chemical composition of the amorphous layer 110 in FIG. 7A.

In some embodiments, the heat dissipating device 100 may be generated by depositing the first material 10 on the substrate comprising the second material 20.

Referring to FIG. 7C, a substrate of the second material 20 with natural oxide may be prepared S210 and the oxide layer 140 may be formed on the substrate of the second material 20 S220.

In some embodiments, the oxide layer 140 may include the natural oxide. Alternatively, the oxide layer 140 may be formed by removal of the natural oxide present on the substrate (through an etching process) and exposure of the substrate with the natural oxide layer removed to air. For example, the hydrofluoric acid may be used in the etching process. The process of etching the natural oxide and the exposure may not be performed depending on the type of the heat dissipating device 100.

The first material 10 may be deposited on the oxide layer 140 on the substrate S230. When the first material 10 is deposited with a predetermined thickness or for a predetermined time, an amorphous layer 110 including the amorphous compound of the first material 10 and the second material 20 may be formed at the bottom of the oxide layer 140.

A crystalline layer and/or an amorphous layer of the first material 10 may be performed at the top of the oxide layer 140. The first material 10 may be formed into the crystalline structure (see FIG. 7A) or may be formed into the amorphous and then formed into the crystalline structure (150 in FIG. 7B) depending on the thickness of the oxide layer 140.

Table 2 below shows characteristics of the manufacturing process of heat dissipating devices 100 GaAs III and Ge III.

TABLE 2

| 2^{nd} material | Index | etching process | air expose duration after etching |
|---|---|---|---|
| GaAs | III | ∘ | 1 hour |
| Ge | III | x | N/A |

Referring to Table 2, the oxide layer 140 of the heat dissipating device GaAs III fabricated from the Gallium arsenide substrate may be formed through the etching process and the air exposure for about 1 hour. As Al is a metal that intercalates relatively well between other materials, Al may pass through the oxide layer 140 on the surface of GaAs III and mix with the Gallium arsenide to form the amorphous layer 110 of Al—GaAs compound between the oxide layer 140 and the second material 20 of the substrate. Referring to FIG. 7a, since the thickness of the oxide layer 140 of GaAs III is relatively thinner than that of Ge III, the first material 10 may be formed on the oxide layer 140 with a crystalline structure.

Referring to Table 2, the oxide layer 140 of the heat dissipating device Ge III fabricated from the germanium substrate may be formed without the etching process and the air exposure. Therefore, the oxide layer 140 of Ge III is from a natural oxidation. When the metal such as Al that intercalates relatively well between other materials is deposited on the surface of Ge III on which the etching process was not performed, metals such as Al may pass through the oxide layer 140 on the surface of Ge III and mix with the gallium arsenide, forming the amorphous layer 110 of Al—Ge compound between the oxide layer 140 and the second material 20 of the substrate.

Referring to FIG. 7b, since the thickness of the oxide layer 140 of Ge III is relatively thicker than that of GaAs III, the first material 10 may form the single amorphous layer 150 of the amorphous structure. Afterwards, the metal subsequently deposited may form the first material 10 of the crystalline structure on the single amorphous layer 150.

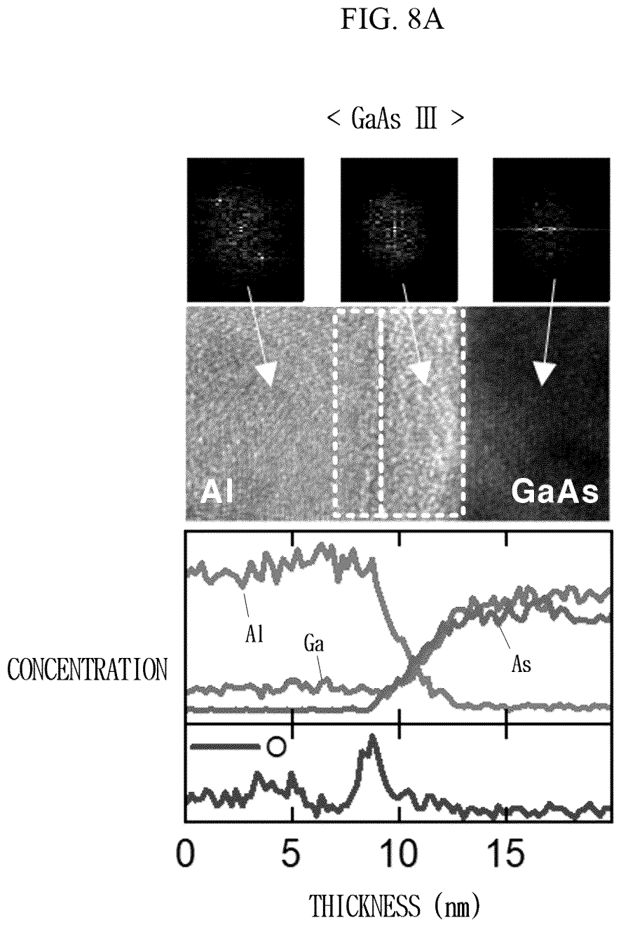

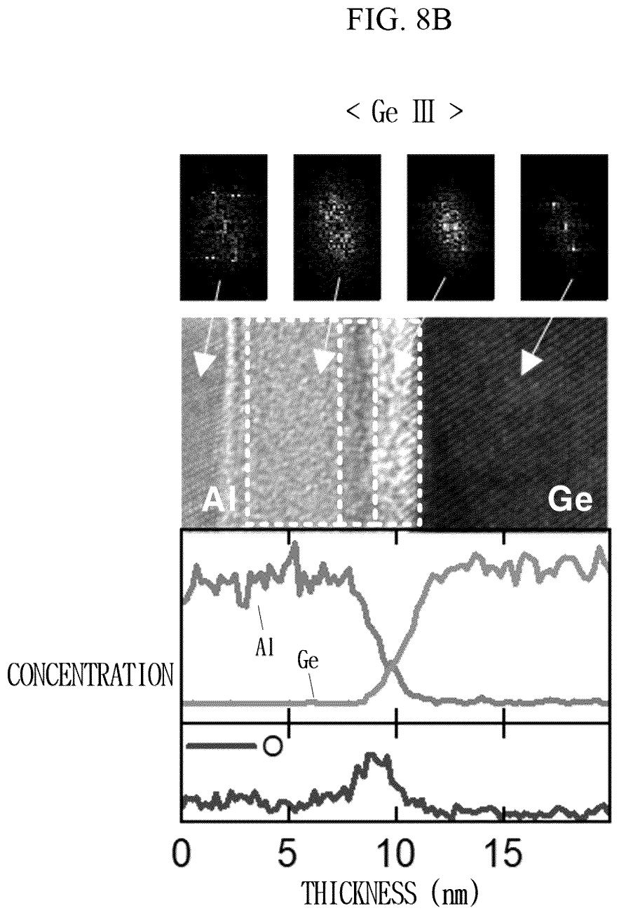

FIG. 8A and FIG. 8B illustrate compositional changes of a heat dissipating device according to one or more embodiments.

FIG. 8A and FIG. 8B illustrate TEM images and EDS depth profiles of the first material, the second material, and the heat dissipating device positioned between the first material and the second material. The FFT images of specific portion of the first material, the heat dissipating device, and the second material in the TEM image are listed in the upper part of FIG. 8A and FIG. 8B.

In FIG. 8A, the first material is polycrystalline aluminum (Al) and the second material is a monocrystalline Gallium arsenide (GaAs) substrate. In FIG. 8B, the first material is polycrystalline aluminum (Al) and the second material is a monocrystalline germanium (Ge) substrate.

Referring to FIG. 8A and FIG. 8B, in the TEM images, the first material (Al) is shown in a light shade and the second materials (GaAs and Ge) are shown in a relatively dark shade. In FIG. 8A and FIG. 8B, dotted line boxes between the first material and the second material may represent layers included in the heat dissipating device.

The O line at the bottom in the EDS depth profiles in FIG. 8A and FIG. 8B represents the concentration of oxygen measured in the first material, the heat dissipating device, and the second material. In FIG. 8A and FIG. 8B, the high concentration of oxygen in the section of thickness between about 7 nm to 10 nm may indicate an oxide layer included in the heat dissipating device illustrated in FIG. 8A and FIG. 8B. The left dotted line box in the TEM image of FIG. 8A represents the oxide layer. The dotted line box in the center of the TEM image in FIG. 8B may represent the oxide layer.

In FIG. 8A, the heat dissipating device GaAs III may include an amorphous layer including an amorphous compound of aluminum and Gallium arsenide. For example, the heat dissipating device GaAs III may have a layered structure such as that shown in FIG. 7a.

The dotted line box on the right in the TEM image of FIG. 8A may indicate the amorphous layer of aluminum-Gallium arsenide compound included in the heat dissipating device GaAs III. Additionally, the dotted line box on the right in the TEM image of FIG. 8B may indicate the amorphous layer of aluminum-germanium compound included in the heat dissipating device Ge III.

For the fabrication of GaAs III, the etching process has been performed, and after the etching process, an air exposure process has been performed for about an hour. In the fabrication of Ge III, no etching process has been performed, and therefore no air exposure process was performed.

In the FFT image of FIG. 8A, both the FFT images of the first material (Al) and second material (GaAs) portion include well-defined diffraction peaks, which may indicate that the first material portion and second material portion are highly crystalline. On the other hand, the FFT image (middle image) of the heat dissipating device portion does not show the diffraction peak, which may indicate the amorphous characteristic of the heat dissipating device.

In FIG. 8A, the EDS depth profile of GaAs III may show the concentration gradient of the first material and the second material. In GaAs III, the aluminum concentration remains high before the amorphous layer within the heat dissipating device, then gradually decreases within the amorphous layer, and becomes substantially zero at the right interface of the amorphous layer. In contrast, the concentration of Gallium arsenide remains substantially 0 before the amorphous layer, then gradually increases within the amorphous layer and reaches a substantially maximum at the right interface of the amorphous layer. Since the concentration of aluminum is continuously maintained in the oxide layer (approximately 2 nm), it may be determined that the oxide layer is composed of aluminum oxide. To the left of the oxide layer is a single amorphous layer of aluminum.

In FIG. 8B, the heat dissipating device Ge III may include an amorphous layer including an amorphous compound of aluminum and germanium, an oxide layer positioned on one side of the amorphous layer, and a single amorphous layer of aluminum positioned on the other side of the oxide layer. For example, the heat dissipating device Ge III may have a layered structure such as that shown in FIG. 3b.

The dotted line boxes in the TEM image of FIG. 8B may represent, from the right, the amorphous layer of the aluminum-germanium compound, the oxide layer, and the single amorphous layer of aluminum.

In the FFT image of FIG. 8B, both the FFT images of the first material (Al) and second material (Ge) portion include well-defined diffraction peaks, which may indicate that the first material portion and second material portion are highly crystalline. In contrast, no diffraction peak appears in the FFT image of the amorphous layer of the heat dissipating device (dotted box on the right), and no diffraction peak appears in the FFT image of the single amorphous layer of the heat dissipating device (dotted box on the left). This may indicate that the amorphous layer and single amorphous layer of the heat dissipating device are not crystalline.

In FIG. 8B, the EDS depth profile of Ge III may show the concentration gradient of the first material and the second material. In Ge III, the aluminum concentration remains high until the single amorphous layer within the heat dissipating device, then gradually decreases within the oxide layer and the amorphous layer, and becomes substantially zero at the right interface of the amorphous layer. In contrast, the concentration of germanium remains substantially 0 until it passes through a single amorphous layer and reaches the oxide layer, then gradually increases within the amorphous layer, and reaches a substantially maximum at the right interface of the amorphous layer.

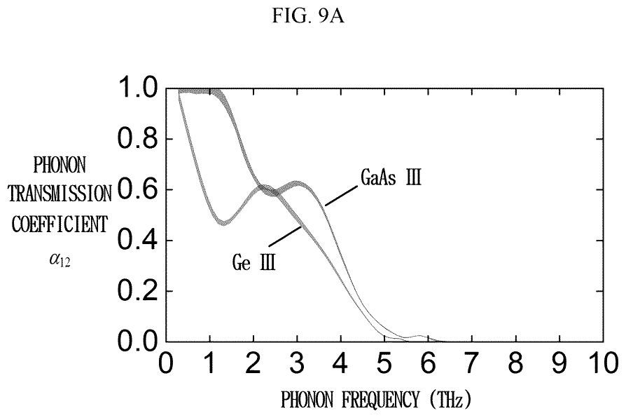

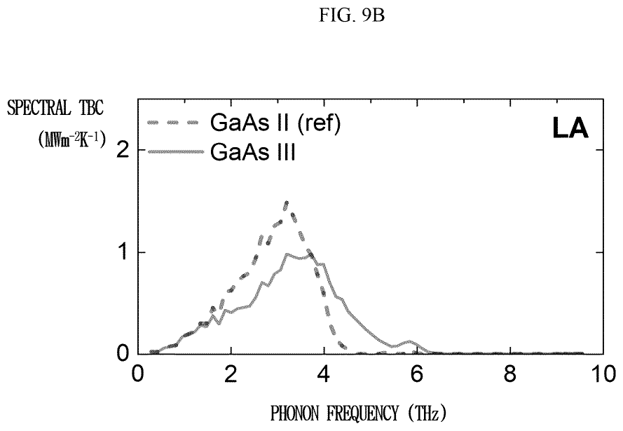

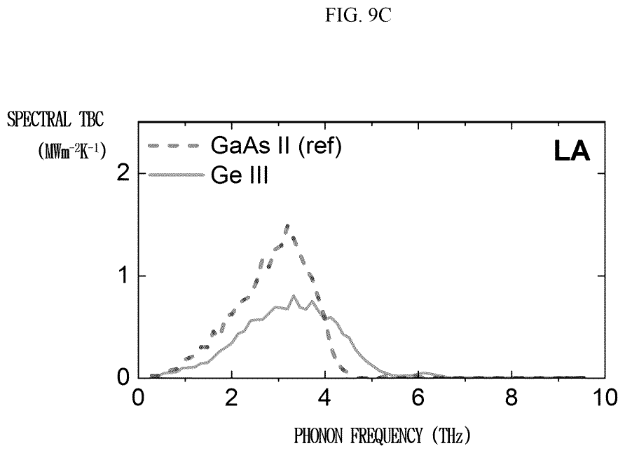

FIG. 9A illustrates phonon transmission coefficients measured at an interface of heat dissipating devices according to one or more embodiments. FIG. 9B and FIG. 9C illustrate spectral TBC of heat dissipating devices according to one or more embodiments.

Referring to FIG. 9A, the phonon transmission coefficients of two different heat dissipating devices GaAs III and Ge III as a function of phonon frequency are shown. FIG.

9A illustrates the transmission coefficient of LA mode phonons in the heat dissipating devices.

FIG. 9B and FIG. 9C illustrates the spectral TBC of the heat dissipating devices GaAs III and Ge III as a function of phonon frequency. FIG. 9B and FIG. 9C illustrate the spectral TBC of the LA mode phonons in the heat dissipating devices.

Referring to FIG. 9A, the phonon transmission coefficient of the heat dissipating devices GaAs III and Ge III do not consistently decrease with increasing phonon frequency, but decrease and then increase again at a certain phonon frequency. Also, referring to FIG. 9B and FIG. 9C, GaAs III and Ge III exhibit higher phonon conductivities at higher phonon frequencies than GaAs II. That is, it may be determined that GaAs III and Ge III may transmit high-frequency phonons better than GaAs II.

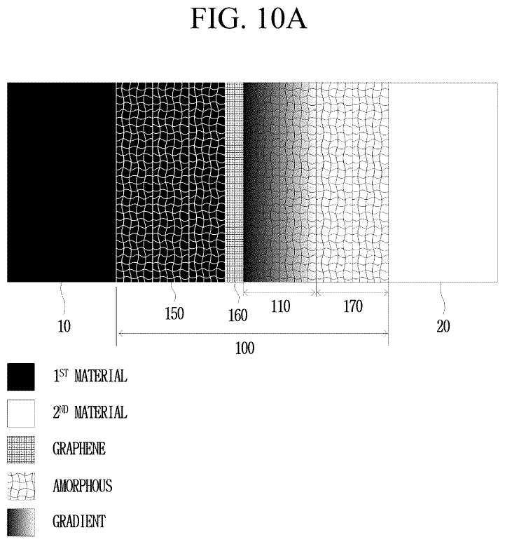

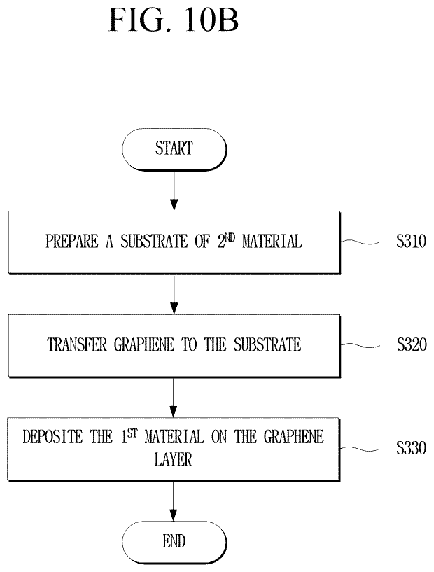

FIG. 10A illustrates a heat dissipating device according to one or more embodiments. FIG. 10B illustrates a method for manufacturing a heat dissipating device according to one or more embodiments.

Referring to FIG. 10A, a heat dissipating device 100 according to one or more embodiments includes an amorphous layer 110 and a graphene layer 160. In addition, The heat dissipating device 100 further includes the first single amorphous layer 150 of the first material 10 and a second single amorphous layer 170 of the second material 20. The first single amorphous layer 150 of the first material is adjacent to the first material 10 and the second single amorphous layer 170 of the second material 20 is adjacent to the second material 20. In FIG. 10A, the first single amorphous layer 150 may substantially include only the first material 10 and may be formed after the graphene layer 160 is formed.

In FIG. 10A, the amorphous layer 110 is between the second single amorphous layer 170 and the graphene layer 160 and the graphene layer 160 is between the amorphous layer 110 and the first single amorphous layer 150.

Referring to FIG. 10A, the amorphous layer 110 may include the amorphous compound of first material 10 and second material 20. Within the amorphous layer 110, the ratio of the first material 10 and the second material 20 may gradually change along the thickness direction of the amorphous layer 110. That is, the amorphous layer 110 may have a concentration gradient of the first material 10 and the second material 20. For example, along the direction from the oxide layer 140 to the second material 20, the first proportion of the first material 10 within the amorphous layer 110 may gradually decrease and the second proportion of the second material 20 may gradually increase.

The first proportion of the first material 10 may be substantially maximum at the part where the amorphous layer 110 is adjacent to the graphene layer 160 or may be substantially maximum within the graphene layer 160. The second proportion of the second material 20 may be substantially maximum where the amorphous layer 110 is adjacent to the second single amorphous layer 170.

In some embodiments, the heat dissipating device 100 may be generated by forming the graphene layer 160 and depositing the first material 10 on the substrate comprising the second material 20.

Referring to FIG. 10B, a substrate of typical commercially available of the second material 20 may be prepared S310 and graphene may be transferred to the substrate to form the graphene layer S320. The natural oxide may be slightly present or substantially absent on the surface of the substrate of the second material 20.

In some embodiments, the graphene layer 160 may be transferred on the substrate of the second material 20 using a support layer such as polymethylmetaacrylate (PMMA).

Deposition of first material 10 may be performed on the graphene layer 160 S330.

In some embodiments, the first material (10) deposited on the graphene layer 160 may pass through the graphene layer 160 and react with the second material 20 of the substrate. For example, the amorphous layer 110 of the heat dissipating device 100 of FIG. 10A may be generated by the reaction between the first material 10 passing through the graphene layer 160 and the second material 20 of the substrate.

In some embodiments, as the amorphous layer 110 is formed on the substrate in the right side of the graphene layer 160 in FIG. 10A, a portion of the substrate that contacts the amorphous layer 110 may also change to the amorphous state. For example, the second single amorphous layer 170 of the heat dissipating device 100 of FIG. 10A may be generated by a portion of the substrate that contacts the amorphous layer 110 being disturbed by the amorphous layer 110.

The first material 10 deposited on the graphene layer 160 may be formed in the amorphous state (that is, the first single amorphous layer 150) and then further formed in the crystalline structure thereon (that is, the portion of the first material 10).

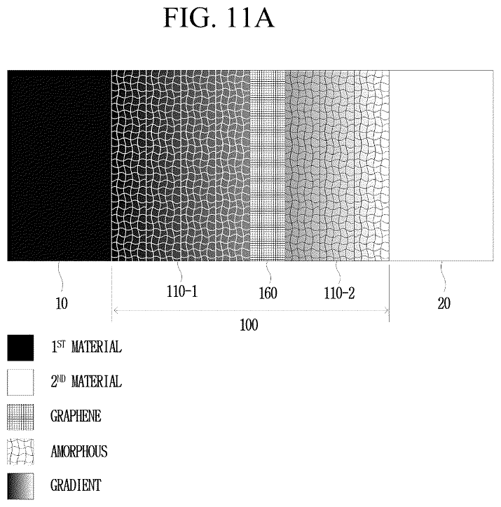

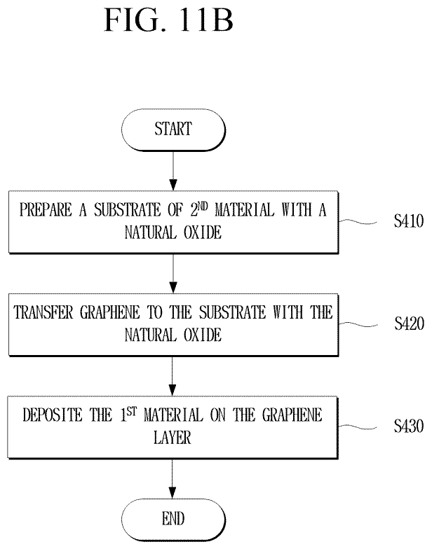

FIG. 11A illustrates a heat dissipating device according to one or more embodiments. FIG. 11B illustrates a method for manufacturing a heat dissipating device according to one or more embodiments.

Referring to FIG. 11A, the heat dissipating device 100 may include a first amorphous layer 110-1, a second amorphous layer 110-2, and the graphene layer 160 inserted between the first amorphous layer 110-1 and the second amorphous layer 110-2.

Referring to FIG. 11A, within the first amorphous layer 110-1 and the second amorphous layer 110-2, a ratio of the first material 10 and the second material 20 gradually changes along the thickness direction of the first amorphous layer 110-1 and the second amorphous layer 110-2. In addition, the concentration gradient of the first material 10 and the second material 20 may be maintained within the graphene layer 160 inserted between the first amorphous layer 110-1 and the second amorphous layer 110-2. That is, the first proportion of the first material 10 may be substantially maximum at the interface where the heat dissipating device 100 contacts the first material 10 and may decrease in the direction from the first material 10 to the second material 20. On the other hand, the second proportion of the second material 20 may be substantially maximum at the interface where the heat dissipating device 100 contacts the second material 20 and may decrease in the direction from the second material 20 to the first material 10.

In some embodiments, the heat dissipating device 100 may be generated by inserting the graphene layer 160 to the substrate of the second material 20 with the natural oxide and depositing the first material 10 on the graphene layer 160.

Referring to FIG. 11B, a substrate of the second material 20 is prepared S410 and the graphene layer 160 may be formed by transferring the graphene to the substrate with the natural oxide S420. The natural oxide of significant thickness may exist on the typical commercially supplied substrate.

In some embodiments, the graphene layer 160 may be transferred during the formation of the amorphous layer 110 using a support layer such as polymethylmetaacrylate (PMMA).

After the graphene layer 160 is transferred, the first material 10 may be deposited on the graphene layer 160 S430. In some embodiments, the second material 20 of the substrate may pass through the graphene layer 160 by the oxygen of the natural oxide layer and react with the first material 10 deposited on the graphene layer 160, so that an amorphous layer 110 including the amorphous compound of the first material 10 and the second material 20 may be generated on the graphene layer 160. The first amorphous layer 110-1 between the graphene layer 160 and the first material 10 in FIG. 11A may be generated by a reaction between the first material 10 and the second material 20 that has passed through the graphene layer 160.

In some embodiments, the first material 10 deposited on the graphene layer 160 may pass through the graphene layer 160 and react with the second material 20 on the substrate. For example, the second amorphous layer 110-2 between the graphene layer 160 and the second material 20 in FIG. 11A may be generated by the reaction between the first material 10 that has passed through the graphene layer 160 and the second material 20 of the substrate.

Table 3 below shows characteristics of the manufacturing process of the heat dissipating devices 100 GaAs IV, Ge IV, and Si V

TABLE 3

| 2^{nd} material | Index | etching process | graphene insertion |
|---|---|---|---|
| GaAs | IV | x | ∘ |
| Ge | IV | x | ∘ |
| Si | V | x | ∘ |

Referring to Table 3, when manufacturing the heat dissipating device GaAs IV from the Gallium arsenide substrate, the heat dissipating device Ge IV from the germanium substrate, and the heat dissipating device Si V from the silicon substrate, the etching process is not performed, but graphene insertion is performed.

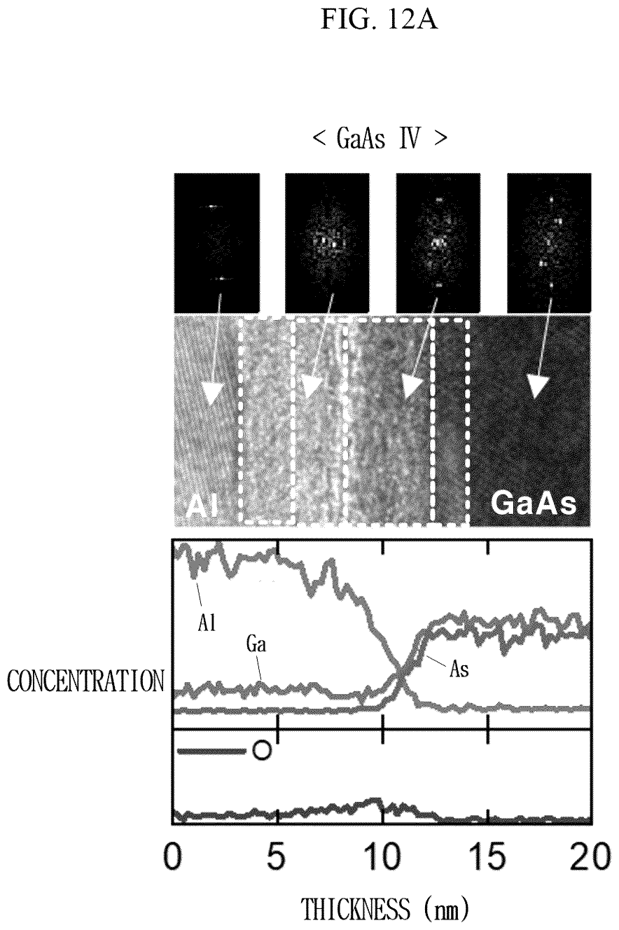

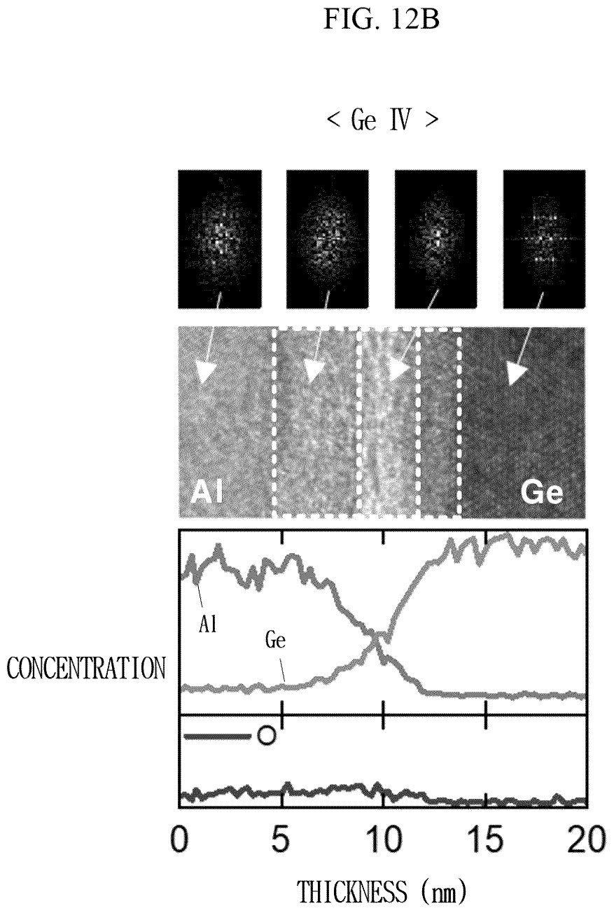

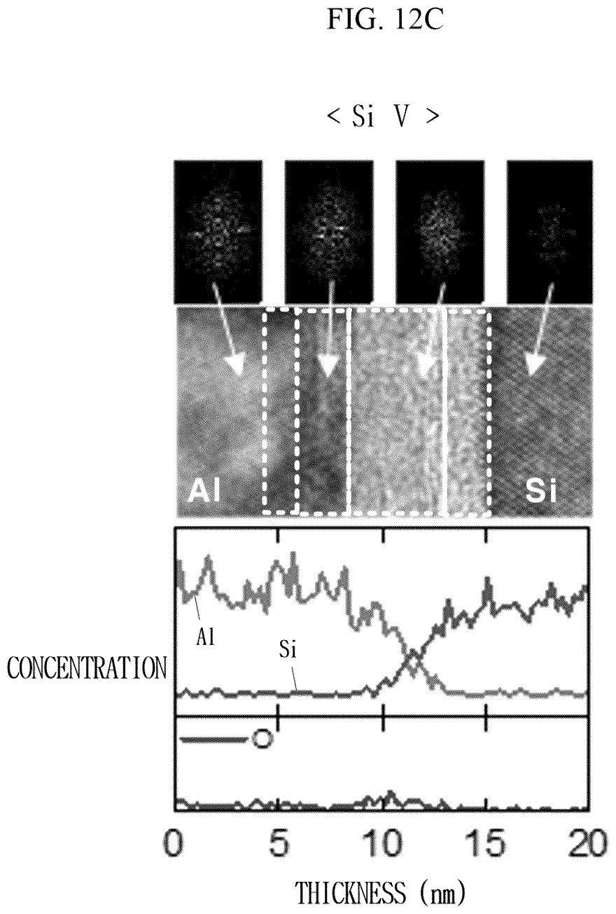

FIG. 12A to FIG. 12C illustrate compositional changes of a heat dissipating device according to one or more embodiments.

FIG. 12A to FIG. 12C illustrate TEM images and EDS depth profiles of the first material, the second material, and the heat dissipating device positioned between the first material and the second material. The FFT images of specific portion of the first material, the heat dissipating device, and the second material in the TEM image are listed in the upper part of FIG. 12A to FIG. 12C.

In FIG. 12A, the first material is polycrystalline aluminum (Al) and the second material is a monocrystalline Gallium arsenide (GaAs) substrate. In FIG. 12B, the first material is polycrystalline aluminum (Al) and the second material is a monocrystalline germanium (Ge) substrate. In FIG. 12C, the first material is polycrystalline aluminum (Al) and the second material is a monocrystalline silicon (Si) substrate.

Referring to FIG. 12A and FIG. 12B, in the TEM images, the first material (Al) is shown in a light shade and the second materials (GaAs and Ge) are shown in a relatively dark shade. Referring to FIG. 12C, in the TEM image, the first material (Al) is shown in a light shade and the second material (20, Si) is shown in a slightly darker shade than the first material. In FIG. 12A to FIG. 12C, the dotted line boxes between the first material and the second material may represent layers included in the heat dissipating device.

In the EDS depth profiles of FIG. 12A to FIG. 12C, the O line at the bottom represents the concentration of oxygen measured in the first material, the heat dissipating device, and the second material. During the fabrication of the heat dissipating device, the first material and the second material may react with the oxygen in the air, so trace amounts of oxygen may exist within the first material, the heat dissipating device, and the second material.

In FIG. 12A, the heat dissipating device GaAs IV may include the amorphous layer including the amorphous compound of aluminum and Gallium arsenide. For example, the heat dissipating device GaAs IV may have a layered structure such as that shown in FIG. 10A and may be fabricated by the method illustrated in FIG. 10B.

The dotted line boxes in the TEM image of FIG. 12A may represent various layers included within the heat dissipating device GaAs IV. The dotted line boxes correspond to, from left to right, the first single amorphous layer, the graphene layer, the compound amorphous layer, and the second single amorphous layer. The first single amorphous layer is an amorphous layer of aluminum, the compound amorphous layer to the right of the graphene layer is an amorphous layer of aluminum-Gallium arsenide compound, and the second single amorphous layer to the right of the amorphous layer is an amorphous layer of Gallium arsenide.

In the FFT image of FIG. 12A, both the FFT images (the first and last images on the left) of the first material (Al) portion and second material (GaAs) portion include well-defined diffraction peaks, which may indicate that the first material portion and second material portion are highly crystalline. The FFT image of the graphene layer (second image on the left) shows the lattice structure of graphene. The FFT image of the amorphous layer (third image on the left) does not show the diffraction peak, which may indicate the characteristic of the amorphous layer.

In FIG. 12A, the EDS depth profile of GaAs IV may show the concentration gradients of the first material and the second material. In GaAs IV, the aluminum concentration remains high before the amorphous layer via the first single amorphous layer, then gradually decreases within the amorphous layer, and becomes substantially zero at the right interface of the amorphous layer. In contrast, the concentration of Gallium arsenide remains substantially 0 before the amorphous layer, then gradually increases within the amorphous layer, and reaches a substantially maximum at the right interface of the amorphous layer.

In FIG. 12B, the heat dissipating device Ge IV includes the amorphous layer including the amorphous compound of aluminum and germanium and the graphene layer inserted in the middle of the amorphous layer. For example, the heat dissipating device Ge IV may have a layered structure such as that shown in FIG. 11A and may be fabricated by the method illustrated in FIG. 11B.

In some embodiments, oxygen in the native oxide layer may induce stronger Al—O and Ge—O bonds than Al—Al and Ge—Ge, and molecules like Ge—O may pass through the graphene layer 160 to form the amorphous metal compound with Al.

The dotted line boxes in the TEM image of FIG. 12B may represent a first amorphous layer of aluminum-germanium compound—graphene layer—a second amorphous layer of aluminum-germanium compound included in the heat dissipating device Ge IV.

In the FFT image of FIG. 12B, both the FFT images (the first and last images on the left) of the first material (Al) and second material (Ge) portion include well-defined diffraction peaks, which may indicate that the first material portion and second material portion are highly crystalline. The FFT image of the amorphous layer (second image on the left) does not show the diffraction peak, which may indicate the characteristic of the amorphous layer. The FFT image of the graphene layer (third image on the left) shows the lattice structure of graphene.

In FIG. 12B, the EDS depth profile of Ge IV may show the concentration gradient of the first material and the second material. In Ge IV, the aluminum concentration remains high before the first amorphous layer within the heat dissipating device, then gradually decreases within the first amorphous layer, the graphene layer, and the second amorphous layer, and becomes substantially zero at the right interface of the second amorphous layer. In contrast, the concentration of germanium remains substantially 0 before the first amorphous layer, then gradually increases within the first amorphous layer, the graphene layer, and the second amorphous layer, and reaches a substantially maximum at the right interface of the second amorphous layer.

Additionally, in FIG. 12B, the oxygen measured at a depth of 0 nm to 10 nm in the EDS depth profile of Ge IV may indicate that the oxygen in the native oxide layer has diffused beyond the graphene layer 160.

In FIG. 12C, the heat dissipating device Si V may include the amorphous layer including the amorphous compound of aluminum and silicon, the graphene layer positioned on one side of the amorphous layer, a first single amorphous layer (Al amorphous layer) positioned on one side of the graphene layer, and a second single amorphous layer (Si amorphous layer) positioned on the other side of the amorphous layer. For example, the heat dissipating device Si V may have a layered structure such as that shown in FIG. 10A and may be fabricated by the method illustrated in FIG. 10B.

The dotted line boxes in the TEM image of FIG. 12C may represent the first single amorphous layer, the graphene layer, the amorphous layer, and the second single amorphous layer in the heat dissipating device Si V.

In the FFT image of FIG. 12C, both the FFT images (the first and last images on the left) of the first material (Al) and second material (Si) portion include well-defined diffraction peaks, which may indicate that the first material portion and second material portion are highly crystalline. The FFT image of the graphene layer (second image on the left) shows the lattice structure of graphene. The FFT image of the amorphous layer (third image on the left) does not show the diffraction peak, which may indicate the characteristic of the amorphous layer.

In FIG. 12C, the EDS depth profile of Si V may show the concentration gradient of the first material and the second material. In Si V, the aluminum concentration remains high before the graphene layer within the heat dissipating device, then gradually decreases within the graphene layer and the amorphous layer, and becomes substantially zero at the right interface of the amorphous layer. In contrast, the concentration of silicon remains substantially 0 before the graphene layer, then gradually increases within the graphene layer and the amorphous layer, and reaches a substantially maximum at the right interface of the amorphous layer.

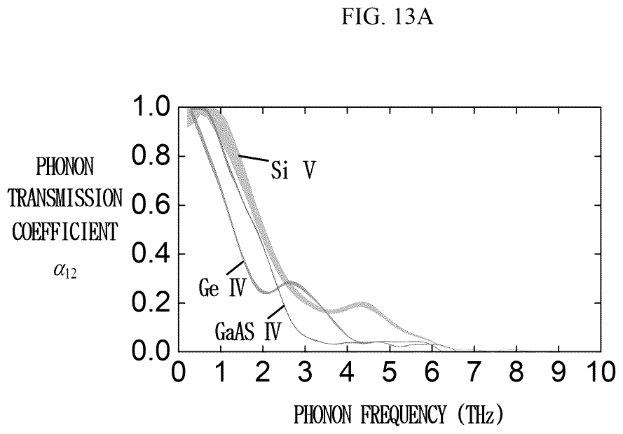

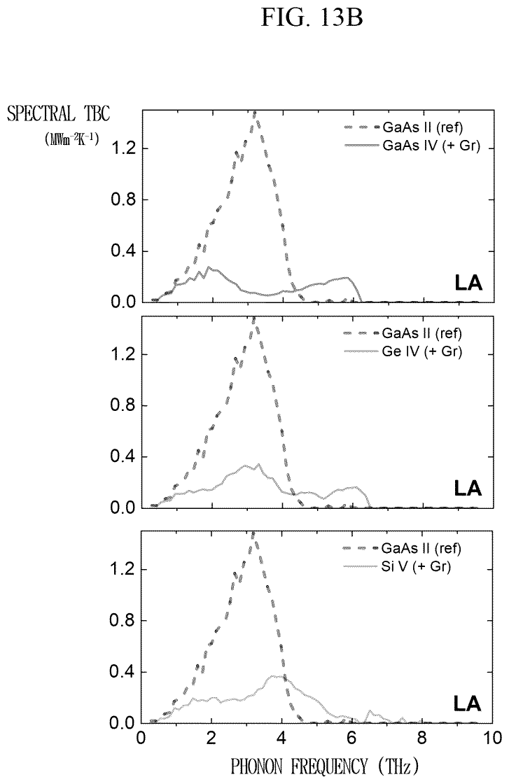

FIG. 13A illustrates phonon transmission coefficients measured at an interface of heat dissipating devices according to one or more embodiments. FIG. 13B illustrates spectral TBC of heat dissipating devices according to one or more embodiments.

Referring to FIG. 13A, the phonon transmission coefficients of three different heat dissipating devices, GaAs IV, Ge IV, and Si V as a function of phonon frequency are shown. FIG. 13A illustrates the transmission coefficient of LA mode phonons in a heat dissipating devices.

FIG. 13B illustrates the spectral TBC of the heat dissipating devices GaAs IV, Ge IV, and Si V as a function of phonon frequency. FIG. 13B illustrates the spectral TBC of the LA mode phonons in the heat dissipating devices.

Referring to FIG. 13A and FIG. 13B, the heat dissipating devices GaAs IV, Ge IV, and Si V tend to transmit higher frequency phonons and transmit lower frequency phonons relatively less than the heat dissipating device GaAs II. For example, the heat dissipating devices GaAs IV, Ge IV, and Si V may transmit high-frequency phonons above 4.5 THz, which GaAs II may not transmit. In other words, the heat dissipation materials GaAs IV, Ge IV, and Si V lack the ability to transmit the low-frequency phonons, but may be used as the frequency conversion filter that transmits relatively high-frequency phonons.

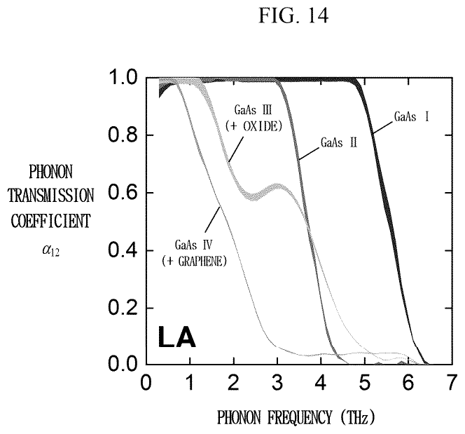

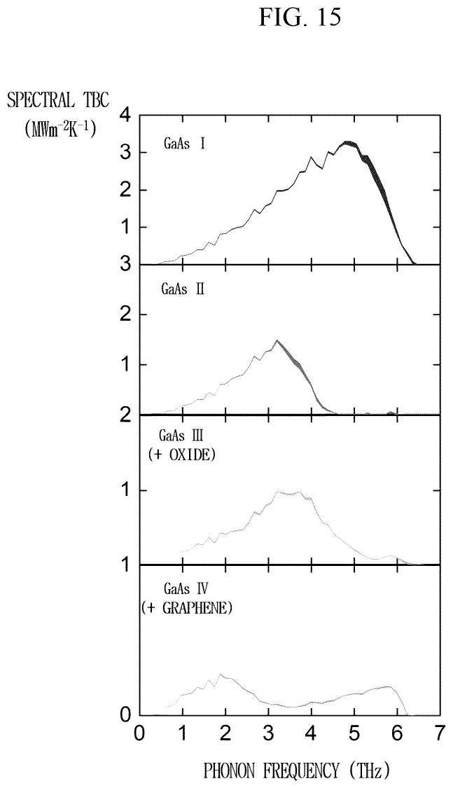

FIG. 14 illustrates phonon transmission coefficients measured at an interface of GaAs series heat dissipating devices according to one or more embodiments. FIG. 15 illustrates spectral TBC of GaAs series heat dissipating devices according to one or more embodiments.

Referring to FIG. 14, it may be seen that GaAs I and GaAs II, which are including the amorphous compound of Al and GaAs, may be used as the low pass filter having a cutoff frequency according to the thickness of the heat dissipating device. In FIG. 14, The cutoff frequency of GaAs I is approximately 4.8 THz, and the cutoff frequency of GaAs II is approximately 3 THz.

Referring to FIG. 15, GaAs III and GaAs IV, which have the amorphous layers with a thickness similar to or thicker than GaAs I and GaAs II, exhibit larger TBC at relatively higher frequencies. It is thought to be due to the oxide layer 140 of GaAs III and the graphene layer 160 of GaAs IV, respectively. The oxide layer 140 of GaAs III and the graphene layer 160 of GaAs IV each have high phonon densities, and thus may transmit the phonons of relatively high frequencies. However, since relatively low-frequency phonons are less transmitted in GaAs III and GaAs IV than in GaAs I and GaAs II, GaAs III and GaAs IV may be used as the frequency conversion filter that sacrifices low-frequency bandwidth phonon transmission to obtain high-frequency bandwidth phonon transmission.

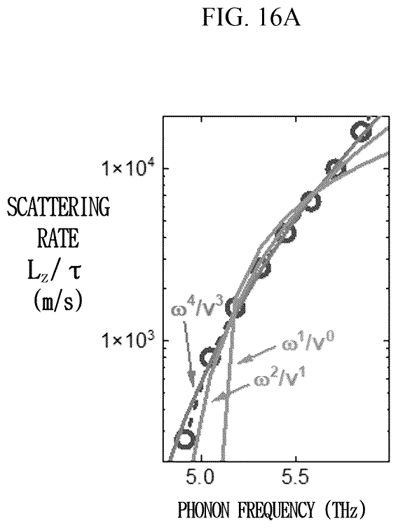

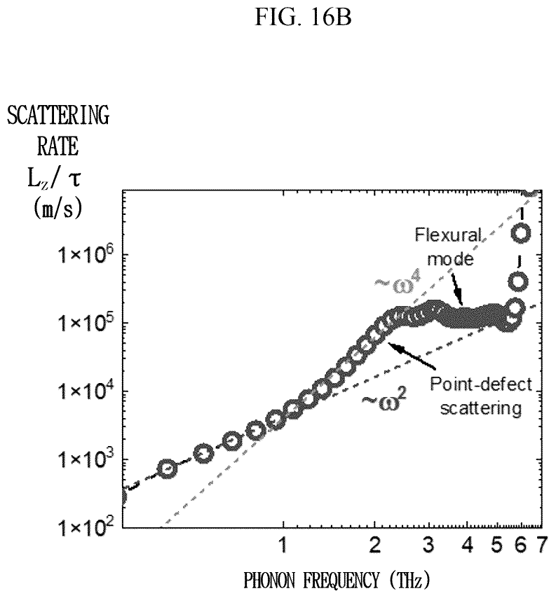

FIG. 16A illustrates scattering ratios for the frequency of the heat dissipating device GaAs I according to one or more embodiments. FIG. 16B illustrates scattering ratios for the frequency of the heat dissipating device GaAs IV according to one or more embodiments.

FIG. 16A illustrates the scattering rate as a function of frequency for the LA mode of GaAs I. Referring to FIG. 16A, the scattering rate L_{z}/τ₁₂ at the interface between medium 1 and medium 2, normalized to L_{z}=1 nm, may be described by the relationship ωⁿ/vⁿ⁻¹ between frequency ω and group velocity @@@. Here, n may represent the scattering mechanism according to the lattice structure. n=1 is dislocation defect scattering, n=2 is line defect scattering, and n=4 is point defect scattering. That is, point defect scattering (ωⁿ/v³ ) is mainly responsible for the steep increase in the scattering rate observed in the high-frequency region, and thus, it may be determined that the decrease of the phonon transmission at high frequencies is due to point defect scattering.

FIG. 16B illustrates the scattering rate as a function of phonon frequency for the LA mode of GaAs IV. Referring to FIG. 16B, it may be seen that the scattering rate, which increases along @@@, no longer increases in the region above the 2 THz frequency. That is, it may be determined that the structure of GaAs IV may transmit relatively high-frequency phonons.

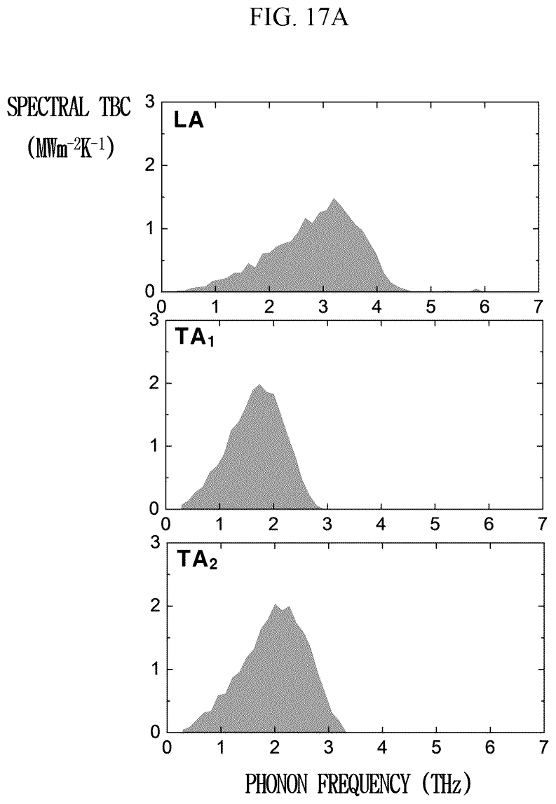

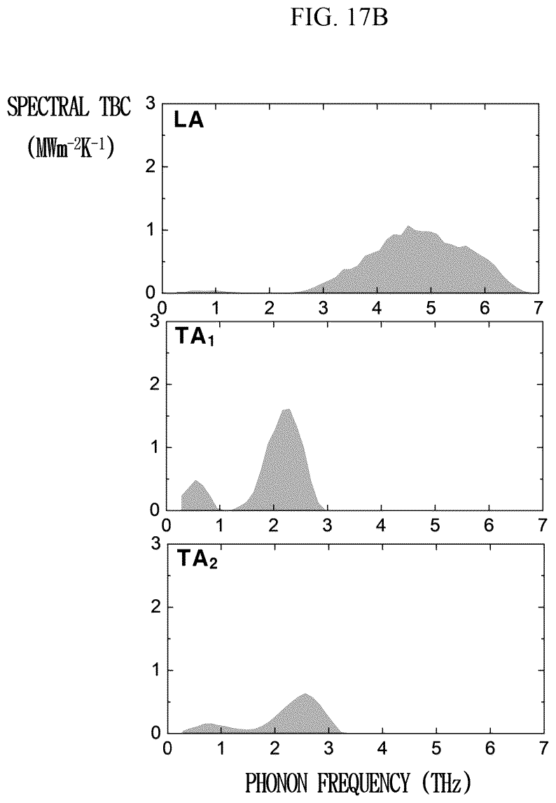

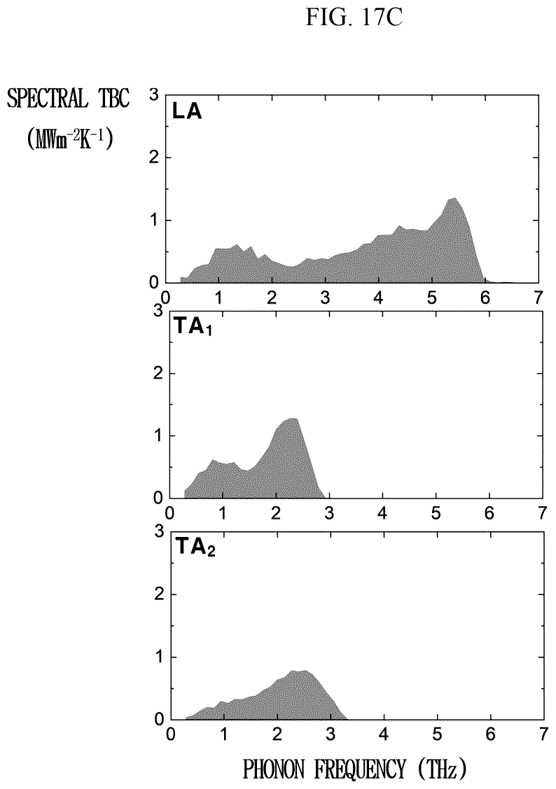

FIG. 17A illustrates spectral TBC about a function of a low-frequency filter of the heat dissipating device GaAs II according to one or more embodiments. FIG. 17B illustrates spectral TBC about a function of a high-frequency filter of the heat dissipating device Ge IV according to one or more embodiments. FIG. 17C illustrates spectral TBC about a function of a frequency conversion filter of the heat dissipating device GaAs IV according to one or more embodiments.

FIG. 17A, FIG. 17B, and FIG. 17C illustrate the spectra TBC of phonons of three polarizations, namely, LA and two horizontal direction traverse acoustic (TA) modes (TA₁ and TA₂).

Referring to FIG. 17A, the heat dissipating device GaAs II including only the amorphous layer mainly transmits the phonons in the low-frequency band and hardly transmits the phonons with the frequency higher than 4 THz. Therefore, GaAs II may function as the low-frequency filter that transmits the low-frequency phonons.

Referring to FIG. 17B, it may be seen that the heat dissipating device Ge IV including the graphene layer in the middle of the amorphous layers may transmit the relatively high-frequency phonons in the 3-7 THz band in the LA mode. Therefore, Ge IV may function as the high-frequency filter that transmits the high-frequency phonons.

Referring to FIG. 17C, it may be seen that GaAs IV including the amorphous layer and the graphene layer and further including the single amorphous layers on both sides of the amorphous layer and the graphene layer may transmit more relatively high-frequency phonons in the 4-6 THz band in the LA mode. GaAs IV transmits less phonons in the low-frequency band than GaAs II using the same semiconductor material, but transmits more phonons in the high-frequency band. Therefore, GaAs IV may function as a filter that equally transmits both low-frequency and high-frequency phonons.

Although the embodiments have been described in detail above, the scope of this disclosure is not limited thereto, and various modifications and improvements of a person of an ordinary skill in the art utilizing the basic concepts defined in the following claims also fall within the scope of this disclosure.

What is claimed is:

1. A thin film structure comprising:
an amorphous layer between a first material and a second material,
wherein the amorphous layer comprises an amorphous compound of the first material and the second material and a ratio of the first material and the second material in the amorphous layer gradually changes along thickness direction of the amorphous layer.

2. The thin film of claim 1, wherein
a first proportion of the first material is substantially maximum where the amorphous layer is adjacent to the first material and a second proportion of the second material is substantially maximum where the amorphous layer is adjacent to the second material.

3. The thin film of claim 1, wherein
the first material is metal, the second material is Gallium arsenide, and the amorphous layer comprises a compound of the metal and the Gallium arsenide.

4. The thin film of claim 1, further comprising:
a first crystalline layer between the first material and the amorphous layer; and
a second crystalline layer between the second material and the amorphous layer,
wherein a first proportion of the first material is substantially maximum where the amorphous layer is adjacent to the first crystalline layer and a second proportion of the second material is substantially maximum where the amorphous layer is adjacent to the second crystalline layer.

5. The thin film of claim 4, wherein
the first crystalline layer comprises a crystalline structure of the first material and the second crystalline layer comprises a crystalline structure of the second material.

6. The thin film of claim 1, further comprising
an oxide layer between the first material and the amorphous layer,
wherein a first proportion of the first material is substantially maximum where the amorphous layer is adjacent to the oxide layer and a second proportion of the second material is substantially maximum where the amorphous layer is adjacent to the second material.

7. The thin film of claim 6, further comprising
a first single amorphous layer between the first material and the oxide layer,
wherein the first single amorphous layer comprises an amorphous structure of the first material.

8. The thin film of claim 7, wherein
the first material is metal and the second material is Germanium.

9. The thin film of claim 1, further comprising
a first single amorphous layer comprising the first material, a second single amorphous layer comprising the second material, and a graphene layer,
wherein the first single amorphous layer is between the first material and the graphene layer, the graphene layer is between the first single amorphous layer and the amorphous layer, and the second single amorphous layer is between the amorphous layer and the second material.

10. The thin film of claim 9, wherein
the first single amorphous layer comprises an amorphous structure of the first material and the second single amorphous layer comprises an amorphous structure of the second material.

11. The thin film of claim 9, wherein
the first material is metal and the second material is Gallium arsenide or Silicon.

12. The thin film of claim 1, further comprising:
a graphene layer,
wherein the graphene layer is inserted in a middle of the amorphous layer.

13. The thin film of claim 12, wherein
the first material is metal and the second material is germanium.

14. A heat dissipating device comprising:
a metal layer;
a semiconductor layer; and
a thin film positioned between the metal layer and the semiconductor layer,
wherein the thin film includes an amorphous compound of metal of the metal layer and a semiconductor of the semiconductor layer and first proportion of the metal gradually decreases within the thin film and second proportion of the semiconductor gradually increases within the thin film along a direction from a first boundary between the thin film and the metal layer to a second boundary between the thin film and the semiconductor layer.
